(19) United States
(12) Patent Application Publication
(10) Pub. No.: US 2024/0086586 A1
(43) Pub. Date: Mar. 14, 2024

(54) MULTI-MODALITY DATA AUGMENTATION ENGINE TO IMPROVE RARE DRIVING SCENARIO DETECTION FOR VEHICLE SENSORS

(71) Applicants: NEC Laboratories America, Inc., Princeton, NJ (US); NEC Corporation, Tokyo (JP)

(72) Inventors: LuAn Tang, Cranbury, NJ (US); Shepard Jiang, Princeton, NJ (US); Peng Yuan, Princeton, NJ (US); Yuncong Chen, Plainsboro, NJ (US); Haifeng Chen, West Windsor, NJ (US); Yuji Kobayashi, Tokyo (JP)

(21) Appl. No.: 18/464,381

(22) Filed: Sep. 11, 2023

Related U.S. Application Data
(60) Provisional application No. 63/406,710, filed on Sep. 14, 2022.

(51) Int. Cl. G06F 30/20; G06N 3/08

(52) U.S. Cl. CPC G06F 30/20; G06N 3/08

(57) ABSTRACT

A computer-implemented method for simulating vehicle data and improving driving scenario detection is provided. The method includes retrieving, from vehicle sensors, key parameters from real data of validation scenarios to generate corresponding scenario configurations and descriptions, transferring target scenario descriptions and validation scenario descriptions to target scenario scripts and validation scenario scripts, respectively, to create first raw simulation data pertaining to target scenario descriptions and second raw simulation data pertaining to validation scenario descriptions, training, by an adjuster network, a deep neural network model to minimize differences between the first raw simulation data and the second raw simulation data, refining the first and second raw simulation data of rare driving scenarios to generate rare driving scenario training data, and outputting the rare driving scenario training data to a display screen of a computing device to enable a user to train a scenario detector for an autonomic driving assistant system.

### RELATED APPLICATION INFORMATION

This application claims priority to Provisional Application No. 63/406,710 filed on Sep. 14, 2022, the contents of which are incorporated herein by reference in their entirety.

### BACKGROUND

### Technical Field

The present invention relates to an autonomic driving assistance system (ADAS) for smart vehicles, and, more particularly, to a multi-modality data augmentation engine to improve rare driving scenario detection for vehicle sensors.

### Description of the Related Art

One key task for an Autonomic Driving Assistant System (ADAS) for smart vehicles is to detect different driving scenarios based on automobile sensor data. The scenario detection component takes the multi-modality sensor data as input, such as the videos from front camera, the global positioning system (GPS) coordinates from sensors and CANBus signals, and outputs the driving scenarios (e.g., another car is cutting in from the left, an ego car is tailgating another car, etc.) so that a central control system can re-act correspondingly.

### SUMMARY

A method for simulating vehicle data and improving driving scenario detection is presented. The method includes retrieving, from vehicle sensors, key parameters from real data of validation scenarios to generate corresponding scenario configurations and descriptions, transferring target scenario descriptions and validation scenario descriptions to target scenario scripts and validation scenario scripts, respectively, to create first raw simulation data pertaining to target scenario descriptions and second raw simulation data pertaining to validation scenario descriptions, training, by an adjuster network, a deep neural network model to minimize differences between the first raw simulation data and the second raw simulation data, refining the first and second raw simulation data of rare driving scenarios to generate rare driving scenario training data, and outputting the rare driving scenario training data to a display screen of a computing device to enable a user to train a scenario detector for an autonomic driving assistant system (ADAS).

A non-transitory computer-readable storage medium comprising a computer-readable program for simulating vehicle data and improving driving scenario detection is presented. The computer-readable program when executed on a computer causes the computer to perform the steps of retrieving, from vehicle sensors, key parameters from real data of validation scenarios to generate corresponding scenario configurations and descriptions, transferring target scenario descriptions and validation scenario descriptions to target scenario scripts and validation scenario scripts, respectively, to create first raw simulation data pertaining to target scenario descriptions and second raw simulation data pertaining to validation scenario descriptions, training, by an adjuster network, a deep neural network model to minimize differences between the first raw simulation data and the second raw simulation data, refining the first and second raw simulation data of rare driving scenarios to generate rare driving scenario training data, and outputting the rare driving scenario training data to a display screen of a computing device to enable a user to train a scenario detector for an autonomic driving assistant system (ADAS).

A system for simulating vehicle data and improving driving scenario detection is presented. The system includes a processor and a memory that stores a computer program, which, when executed by the processor, causes the processor to retrieve, from vehicle sensors, key parameters from real data of validation scenarios to generate corresponding scenario configurations and descriptions, transfer target scenario descriptions and validation scenario descriptions to target scenario scripts and validation scenario scripts, respectively, to create first raw simulation data pertaining to target scenario descriptions and second raw simulation data pertaining to validation scenario descriptions, train, by an adjuster network, a deep neural network model to minimize differences between the first raw simulation data and the second raw simulation data, refine the first and second raw simulation data of rare driving scenarios to generate rare driving scenario training data, and output the rare driving scenario training data to a display screen of a computing device to enable a user to train a scenario detector for an autonomic driving assistant system (ADAS).

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a block/flow diagram of an exemplary driving scenario detector, in accordance with embodiments of the present invention;

FIG. 2 is a block/flow diagram of an exemplary enhanced detection framework with a multi-modality data augmentation engine (MDAE), in accordance with embodiments of the present invention;

FIG. 3 is a block/flow diagram of an exemplary flow chart of the MDAE, in accordance with embodiments of the present invention;

FIG. 4 is a block/flow diagram of an exemplary data simulation process, in accordance with embodiments of the present invention;

FIG. 5 is a block/flow diagram of an exemplary process for training a data adjuster, in accordance with embodiments of the present invention;

FIG. 6 is a block/flow diagram of an exemplary process for refinement for a target scenario, in accordance with embodiments of the present invention;

FIG. 7 is a block/flow diagram of an exemplary process for simulating the driving data to train the driving scenario detection models and to train the data adjuster, in accordance with embodiments of the present invention;

FIG. 8 is a block/flow diagram of an exemplary process for data augmentation for rare driving scenario detection by employing the MDAE, in accordance with embodiments of the present invention;

FIG. 9 is a block/flow diagram of an exemplary processing system for employing the MDAE, in accordance with embodiments of the present invention; and

FIG. 10 is a block/flow diagram of an exemplary method for employing the MDAE, in accordance with embodiments of the present invention.

### DETAILED DESCRIPTION OF PREFERRED EMBODIMENTS

Even with advanced technology of deep neural networks, the accuracy of scenario detection is still a concern. The main challenge is on the data, that is, the training data for some specific driving scenarios are very limited. For example, another car suddenly cuts in from the left or right. In the real world, the drivers must drive for months to collect data related to such a case. The users will spend lots of time to watch all the videos and label out such a unique or rare scenario. Indeed, it is very costly and error-prone for a human to watch the long videos and label out the rare scenarios just to acquire, e.g., a ten second clip. As a result, even the car manufacturer companies collect hundreds of days of data, and they may only have a dozen samples of such rare scenarios. Unfortunately, to train a qualified model (e.g., a deep neural network), the system usually needs thousands of samples. Without enough training data, the model will suffer from the problem of “under-fitting.” Such solution has both high false positives and false negatives in the scenario detection results.

Since it is very costly to ask the end user to provide more training data, the only way to solve this problem is to generate such training data by simulation. The exemplary embodiments of the present invention introduce a Multi-modality Data Augmentation Engine (MDAE) to simulate automobile or vehicle data to improve the driving scenario detection for an autonomic driving assistance system (ADAS) of vehicles or automobiles.

MDAE can generate the labeled data for both common and rare driving scenarios. The exemplary system evaluates the data quality by comparing the generated data with real data of the common scenario, and trains a component referred to as an “adjuster.” The adjuster will then be applied to refine the generated data of rare scenarios and improve their quality. Finally, such refined data will be used to train the scenario detector for ADAS.

The major challenges for multi-modality data augmentation, and its application on driving scenario detection are listed as follows:

Dynamic data, that is, the automobile sensor data are highly dynamic and noisy.

Complex scenarios, that is, the driving scenario involves multiple entities, e.g., a “cut-in from left” scenario includes two cars (ego car and another car), lane constraints and changes, speed control of both cars, etc. The ego vehicle means a vehicle which has primary interest in testing, trailing or operational scenarios.

Large number of generated samples, that is, to train a deep neural network, the system needs to generate thousands of data samples.

Differences between generated data and real data, that is, there are differences between the generated data and the real data. However, such differences may cause both false positives and false negatives in the scenario detection system. Hence, a mechanism (e.g., an adjuster or data adjuster or data model adjuster) is needed to reduce the differences.

MDAE is designed to generate high quality data for rare driving patterns. Compared to traditional solutions like Carla, MDAE can generate high quality data (significantly improve the performance of the detector) and higher efficiency (by only generating the data of specific scenarios). MDAE does not need any real data of the rare scenarios as input (which is very hard to get in real data), and instead MDAE only needs the data of common scenarios. MDAE can generate complex driving scenarios involving the ego car and other surrounding cars.

The main unique features of MDAE are to simulate the driving scenarios by description/configuration, to use real common scenario data to train the adjuster and further refine the simulated rare scenario data, and to significantly improve the accuracy of the scenario detector by providing high quality labeled data as training input.

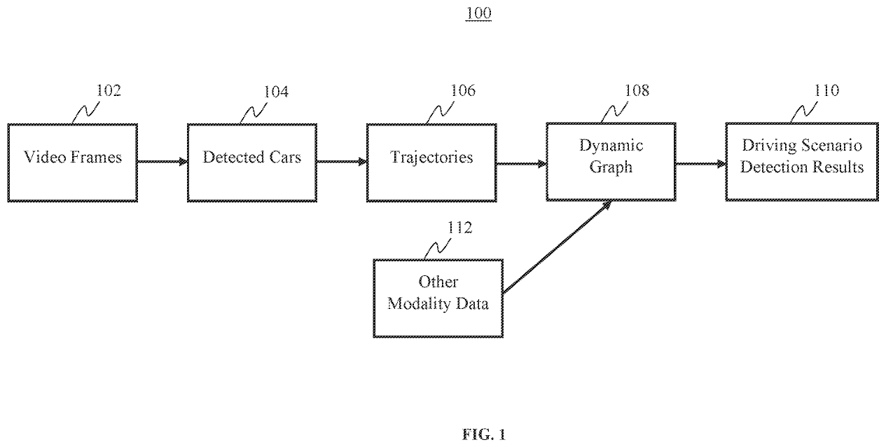

FIG. 1 is a block/flow diagram of an exemplary driving scenario detector, in accordance with embodiments of the present invention.

The exemplary driving scenario detector 100 includes object/car identification from video cameras that detect cars 104 in each frame 102 of the video. Object/car tracking takes the detected cars 104 in each frame 102 as input and tracks their trajectories 106 among multiple frames. The output is the car trajectories 106 retrieved from the video. Next, the multi-modality data is integrated or combined with other modality data 112 to construct a dynamic graph 108. Then, driving scenarios based on the dynamic graph 108 are detected in block 110.

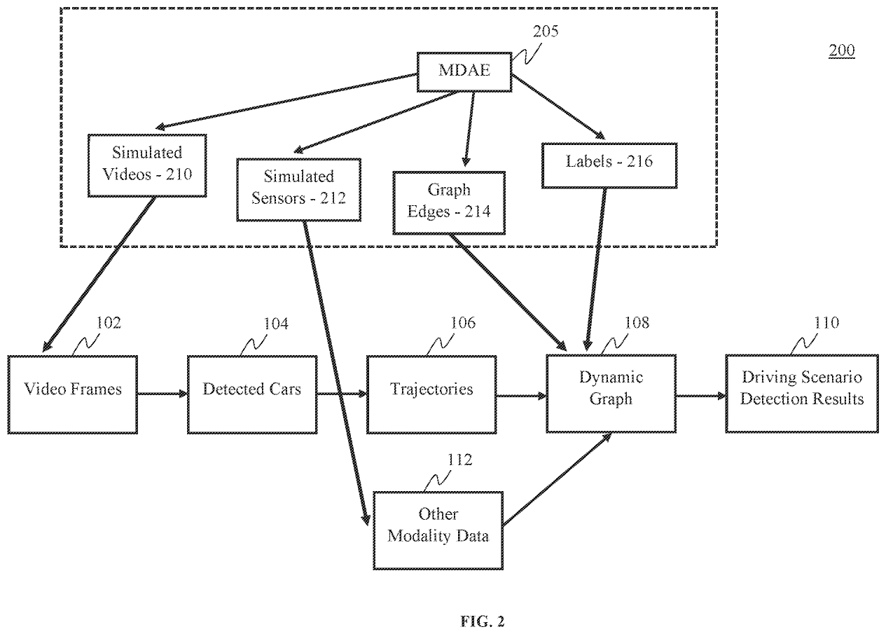

FIG. 2 is a block/flow diagram of an exemplary enhanced detection framework 200 with a multi-modality data augmentation engine (MDAE), in accordance with embodiments of the present invention.

MDAE 205 can be used in at least two manners. In one manner, MDAE 205 generates the videos 210 and raw sensor data 212, such data being used from the beginning of the detection framework 200 and put through all the modules. Graph edges 214 and labels 216 can also be utilized. In another manner, MDAE 205 can directly generate the dynamic graph 108 and can be applied directly for the driving scenario detection of FIG. 1. In this way, the exemplary methods can directly improve the performance of the detection module.

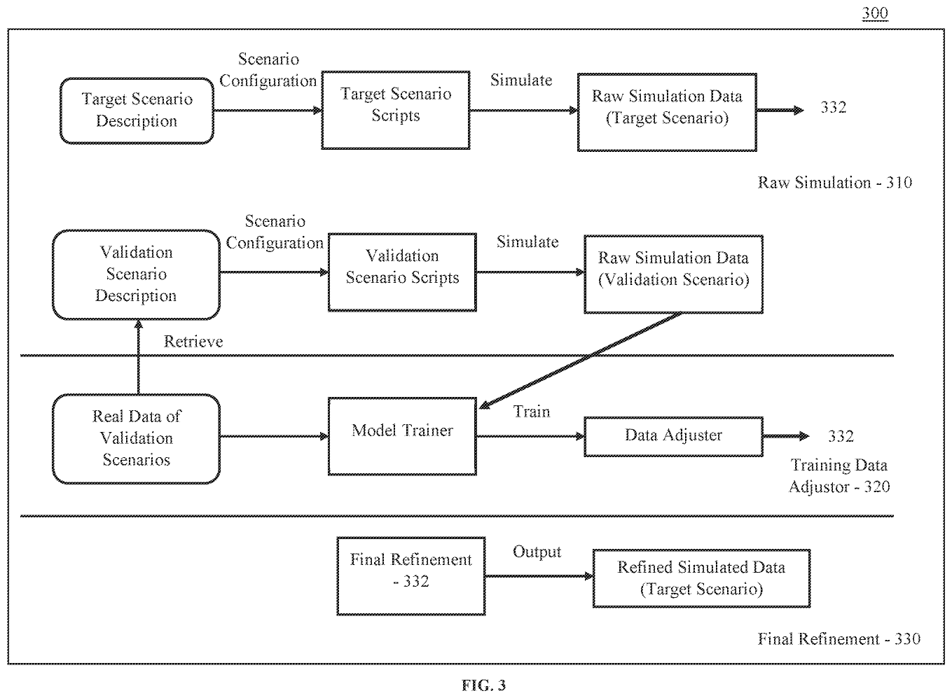

FIG. 3 is a block/flow diagram of an exemplary flow chart 300 of the MDAE, in accordance with embodiments of the present invention.

Regarding raw data simulation 310, the system first retrieves the key parameters from the real data of validation scenarios and generates the corresponding configuration/descriptions. Then the system takes the descriptions of both scenarios as input (target scenario and validation scenario). The descriptions are transferred to the scripts in a pipeline and then run on a simulation platform (e.g., Carla) to generate the data in a required format (e.g., videos, sensors, etc.).

Regarding training adjuster models 320, MDAE takes both simulated data and real data of the validation scenario as input and trains a deep neural network model to minimize the differences between these datasets.

Regarding final refinement 330, MDAE uses the trained adjuster to refine the raw simulated data of rare scenarios and outputs the refined data. The raw simulation 310 and the training data adjuster 320 provide the data to the final refinement 332.

The first task of MDAE 205 is to retrieve the scenario descriptions from the real validation datasets. For each dataset, the exemplary methods retrieve the key parameters, including ego car speed, lane information, other car location, etc.

Meanwhile, it is also expected that the end user can provide some general descriptions of the target scenario. It is noted that users do not need to provide the detailed numbers for speed and direction. MDAE 205 has a random parameter generator, and the users only need to specify the lower bound and upper bound, and MDAE 205 generates multiple scenarios with random values.

With the descriptions of both target and validate scenarios, MDAE 205 will then generate the simulations scripts. The simulation scripts are coded in a programming language that can be directly running on a simulation platform. In exemplary embodiments of the present invention, Scenic (https://scenic-lang.readthedocs.io/en/latest/) is used as the programming language and Carla (https://carla.org/) is used as the simulation platform.

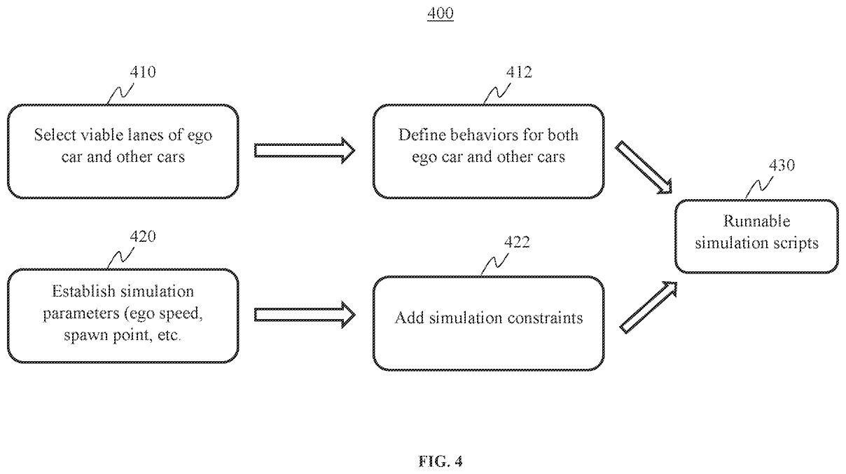

FIG. 4 is a block/flow diagram of an exemplary data simulation process 400, in accordance with embodiments of the present invention.

There are two steps to generate the simulation scripts, that is:

The first is a position and behavior definition. The exemplary methods need to compute the positions of the ego car and other cars, and define their behavior (e.g., following, lane change, etc.) based on the scenario description. The system will first determine on which lanes the ego car and other car are located at (410), and then define their behaviors by adding a behavior function (412).

The second is a parameter and constraints definition. The exemplary methods need to establish the simulation parameters, environments and constraints (420). Certain key parameters are generated in random format based on the value range provided by scenario description, including the passing speed, max break threshold, and so on. The system will also generate the constraints for driving scenarios (422), e.g., whether the ego car can see the other car, minimum distance between ego car and passing car, etc.

The data simulation process 400 will produce runnable simulation scripts 430.

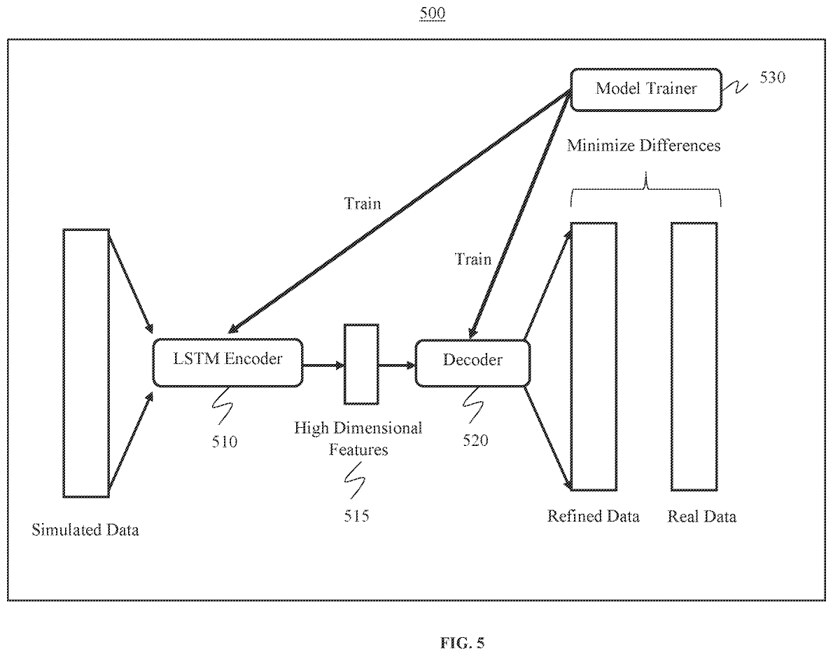

FIG. 5 is a block/flow diagram of an exemplary process for training the adjuster 500, in accordance with embodiments of the present invention.

A major challenge of automobile data simulation relates to the difference between simulated data and real data. Due to the limitation of simulation software (e.g., Carla) and the complexity of automobile sensors, there might be significant differences between the simulated data and the real data.

To deal with this problem, the exemplary methods design an adjuster network 500 for MDAE 205. The adjuster network includes two deep neural networks, that is, a long short-term memory (LSTM) encoder network 510 to transform the simulated data into high dimensional features 515 and a decoder network 520 to construct the refined data from the high dimensional features 515. To train these two networks, the model trainer 530 takes the simulated data from the validation scenario as input, and outputs the refined data. Then the model trainer 530 compares the refined data with the real data of validation scenario and computes their difference. The training goal is to minimize this difference. The model trainer 530 feeds back the difference and adjusts the gradients of the encoder and decoder networks 510, 520. This training process is conducted for several epochs, until the epoch number reaches a predefined threshold.

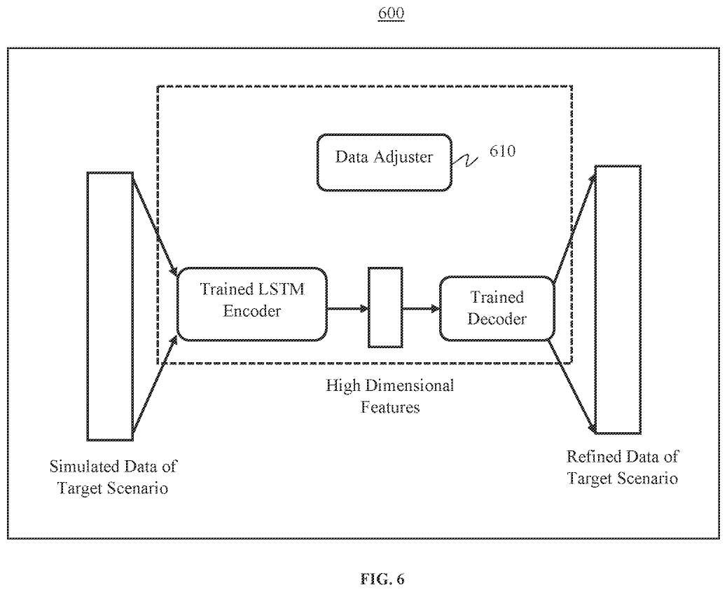

FIG. 6 is a block/flow diagram of an exemplary process for refinement for a target scenario 600, in accordance with embodiments of the present invention.

The MDAE 205 inputs the simulated data of target scenario to the trained data adjuster 610, and outputs the refined data of target scenario. Such data are adjusted as close as the data collected from real sensors. The exemplary methods can further use them to train other deep neural network models such as driving scenario recognition.

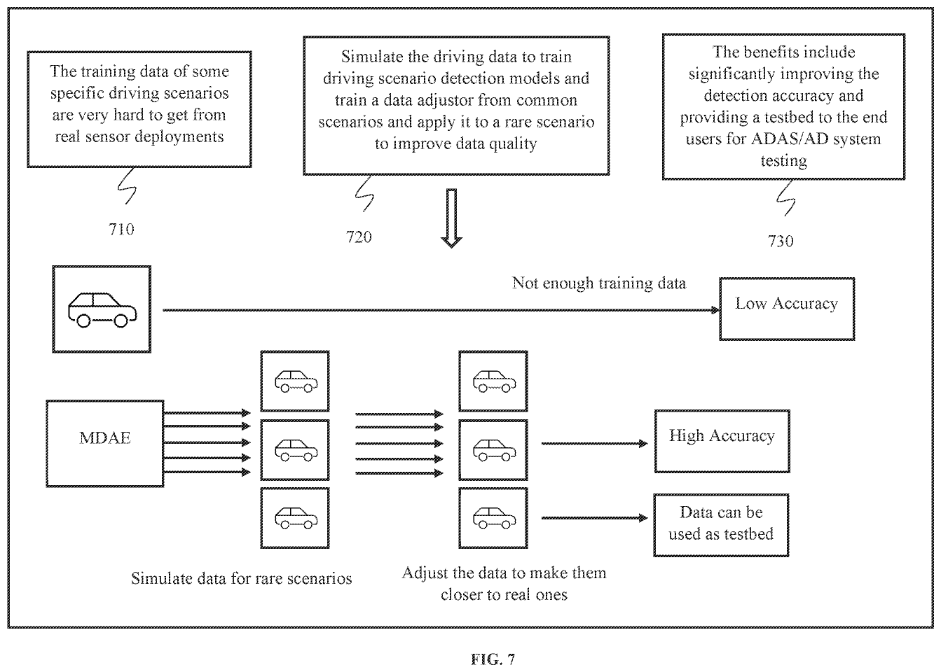

FIG. 7 is a block/flow diagram of an exemplary process for simulating the driving data to train the driving scenario detection models and to train a data adjuster, in accordance with embodiments of the present invention.

At block 710, the issue is that the training data of some specific driving scenarios are very hard to get from real sensor deployments.

At block 720, the solution provides for simulating the driving data to train driving scenario detection models and training a data adjuster from common scenarios and apply it to a rare scenario to improve data quality.

At block 730, the benefits include significantly improving the detection accuracy and providing a testbed to the end users for ADAS/AD system testing.

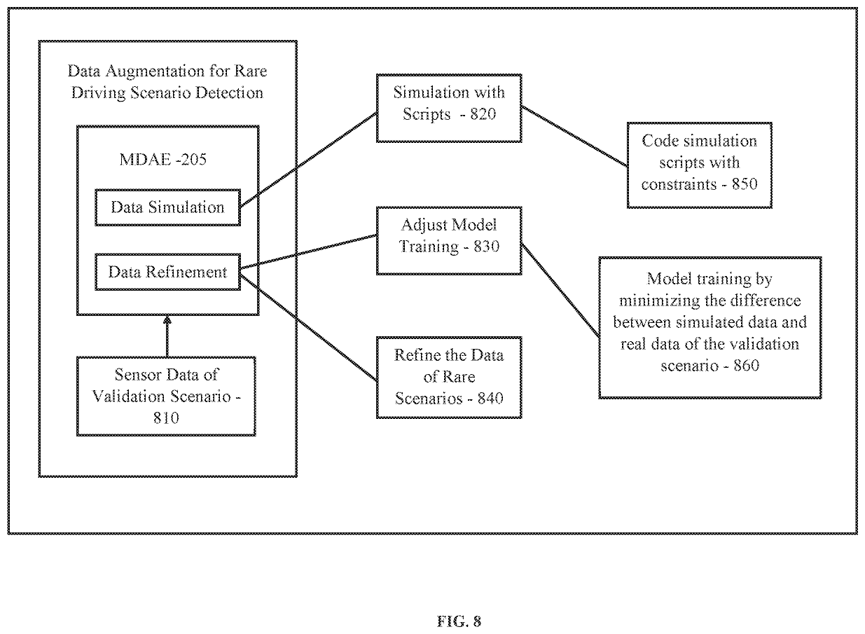

FIG. 8 is a block/flow diagram of an exemplary process for data augmentation for rare driving scenario detection by employing the MDAE, in accordance with embodiments of the present invention.

MDAE 205 includes data simulation and data refinement. Sensor data of the validation scenario 810 is provided to the MDAE 205. The data simulation involves simulation with scripts 820, whereas the data refinement involves adjusting model training 830 and refining the data of rare scenarios 840. The simulation with scripts 820 employees code simulation scripts with constraints 850. The adjustment to the model training 830 involves model training by minimizing the difference between simulated data and real data of the validation scenario 860.

In conclusion, the exemplary methods propose a Multi-modality Data Augmentation Engine (MDAE) to generate high quality training data for rare driving scenarios. The exemplary methods make the following assumptions for this task, which is reasonable and can be achieved easily in real applications. The user can provide the knowledge of rare driving scenarios in advance (e.g., users can describe the rare driving scenarios). The user can provide the real training data of common scenarios. The input of the MDAE 205 is listed as follows:

Description of rare driving scenarios as the target scenario and the real data of common scenario, which are used as the validation scenario data.

The output of the MDAE 205 is the simulated data of the target scenario (rare scenarios) with generated labels. The main innovation is building a pipeline to configure the scenarios and generate the simulated multi-modality data and designing an adjuster to refine the generated data. Compared to other car data simulation systems, MDAE 205 can generate much higher quality data for rare driving scenarios. It is noted that MDAE 205 is used to provide the training data for machine learning/deep neural network-based scenario detection solutions.

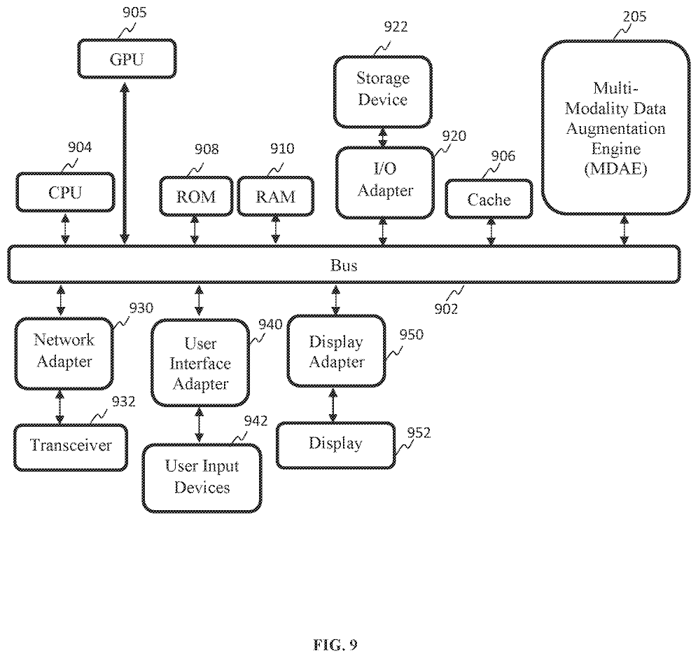

FIG. 9 is an exemplary processing system for employing the MDAE, in accordance with embodiments of the present invention.

The processing system includes at least one processor (CPU) 904 operatively coupled to other components via a system bus 902. A GPU 905, a cache 906, a Read Only Memory (ROM) 908, a Random Access Memory (RAM) 910, an input/output (I/O) adapter 920, a network adapter 930, a user interface adapter 940, and a display adapter 950, are operatively coupled to the system bus 902. Additionally, MDAE 205 communicates with the bus 902.

A storage device 922 is operatively coupled to system bus 902 by the I/O adapter 920. The storage device 922 can be any of a disk storage device (e.g., a magnetic or optical disk storage device), a solid-state magnetic device, and so forth.

A transceiver 932 is operatively coupled to system bus 902 by network adapter 930.

User input devices 942 are operatively coupled to system bus 902 by user interface adapter 940. The user input devices 942 can be any of a keyboard, a mouse, a keypad, an image capture device, a motion sensing device, a microphone, a device incorporating the functionality of at least two of the preceding devices, and so forth. Of course, other types of input devices can also be used, while maintaining the spirit of the present invention. The user input devices 942 can be the same type of user input device or different types of user input devices. The user input devices 942 are used to input and output information to and from the processing system.

A display device 952 is operatively coupled to system bus 902 by display adapter 950.

Of course, the processing system may also include other elements (not shown), as readily contemplated by one of skill in the art, as well as omit certain elements. For example, various other input devices and/or output devices can be included in the system, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized as readily appreciated by one of ordinary skill in the art. These and other variations of the processing system are readily contemplated by one of ordinary skill in the art given the teachings of the present invention provided herein.

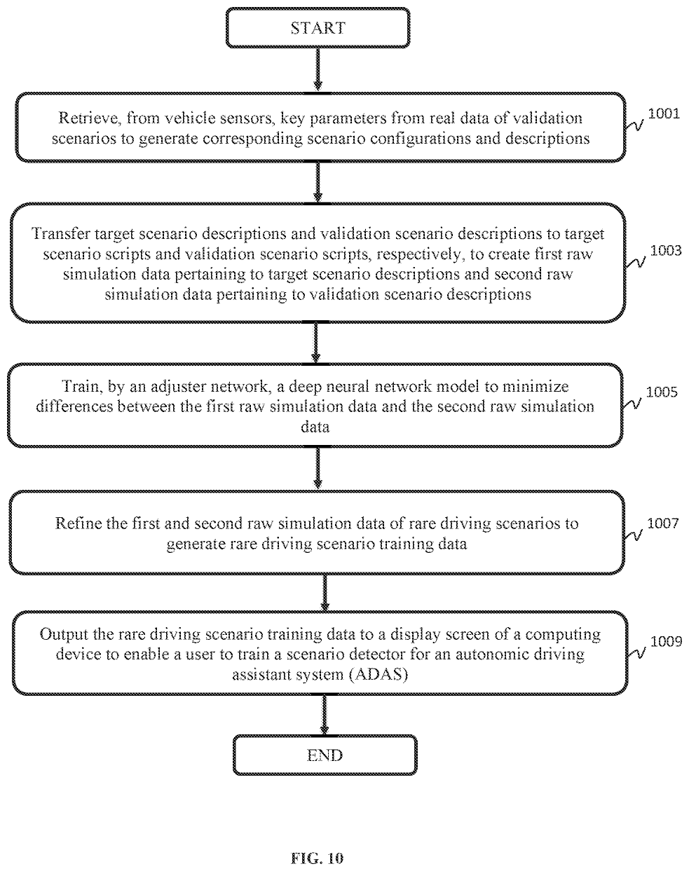

FIG. 10 is a block/flow diagram of an exemplary method for employing the MDAE, in accordance with embodiments of the present invention.

At block 1001, retrieve, from vehicle sensors, key parameters from real data of validation scenarios to generate corresponding scenario configurations and descriptions.

At block 1003, transfer target scenario descriptions and validation scenario descriptions to target scenario scripts and validation scenario scripts, respectively, to create first raw simulation data pertaining to target scenario descriptions and second raw simulation data pertaining to validation scenario descriptions.

At block 1005, train, by an adjuster network, a deep neural network model to minimize differences between the first raw simulation data and the second raw simulation data.

At block 1007, refine the first and second raw simulation data of rare driving scenarios to generate rare driving scenario training data.

At block 1009, output the rare driving scenario training data to a display screen of a computing device to enable a user to train a scenario detector for an autonomic driving assistant system (ADAS).

As used herein, the terms “data,” “content,” “information” and similar terms can be used interchangeably to refer to data capable of being captured, transmitted, received, displayed and/or stored in accordance with various example embodiments. Thus, use of any such terms should not be taken to limit the spirit and scope of the disclosure. Further, where a computing device is described herein to receive data from another computing device, the data can be received directly from the another computing device or can be received indirectly via one or more intermediary computing devices, such as, for example, one or more servers, relays, routers, network access points, base stations, and/or the like. Similarly, where a computing device is described herein to send data to another computing device, the data can be sent directly to the another computing device or can be sent indirectly via one or more intermediary computing devices, such as, for example, one or more servers, relays, routers, network access points, base stations, and/or the like.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module,” “calculator,” “device,” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical data storage device, a magnetic data storage device, or any suitable combination of the foregoing. In the context of this document, a computer readable storage medium may be any tangible medium that can include, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the present invention. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks or modules.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks or modules.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks or modules.

It is to be appreciated that the term “processor” as used herein is intended to include any processing device, such as, for example, one that includes a CPU (central processing unit) and/or other processing circuitry. It is also to be understood that the term “processor” may refer to more than one processing device and that various elements associated with a processing device may be shared by other processing devices.

The term “memory” as used herein is intended to include memory associated with a processor or CPU, such as, for example, RAM, ROM, a fixed memory device (e.g., hard drive), a removable memory device (e.g., diskette), flash memory, etc. Such memory may be considered a computer readable storage medium.

In addition, the phrase “input/output devices” or “I/O devices” as used herein is intended to include, for example, one or more input devices (e.g., keyboard, mouse, scanner, etc.) for entering data to the processing unit, and/or one or more output devices (e.g., speaker, display, printer, etc.) for presenting results associated with the processing unit.

The foregoing is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the principles of the present invention and that those skilled in the art may implement various modifications without departing from the scope and spirit of the invention. Those skilled in the art could implement various other feature combinations without departing from the scope and spirit of the invention. Having thus described aspects of the invention, with the details and particularity required by the patent laws, what is claimed and desired protected by Letters Patent is set forth in the appended claims.

What is claimed is:

1. A computer-implemented method for simulating vehicle data and improving driving scenario detection, the method comprising:
retrieving, from vehicle sensors, key parameters from real data of validation scenarios to generate corresponding scenario configurations and descriptions;
transferring target scenario descriptions and validation scenario descriptions to target scenario scripts and validation scenario scripts, respectively, to create first raw simulation data pertaining to target scenario descriptions and second raw simulation data pertaining to validation scenario descriptions;
training, by an adjuster network, a deep neural network model to minimize differences between the first raw simulation data and the second raw simulation data;
refining the first and second raw simulation data of rare driving scenarios to generate rare driving scenario training data; and
outputting the rare driving scenario training data to a display screen of a computing device to enable a user to train a scenario detector for an autonomic driving assistant system (ADAS).

2. The computer-implemented method of claim 1, wherein the target scenario scripts and the validation scenario scripts are generated based on position and behavior definitions, and parameter and constraints definitions.

3. The computer-implemented method of claim 1, wherein the adjuster network includes a long short-term memory (LSTM) encoder and a decoder.

4. The computer-implemented method of claim 3, wherein the LSTM encoder transforms the first and second raw simulation data into high dimensional features.

5. The computer-implemented method of claim 4, wherein the decoder constructs the rare driving scenario training data from the high dimensional features.

6. The computer-implemented method of claim 5, wherein a model trainer takes the first and second raw simulation data as input and outputs the rare driving scenario training data.

7. The computer-implemented method of claim 6, wherein the model trainer compares the rare driving scenario training data with the real data of the validation scenario and determines a difference therebetween to be minimized.

8. A computer program product for simulating vehicle data and improving driving scenario detection, the computer program product comprising a non-transitory computer readable storage medium having program instructions embodied therewith, the program instructions executable by a computer to cause the computer to perform a method comprising:
retrieving, from vehicle sensors, key parameters from real data of validation scenarios to generate corresponding scenario configurations and descriptions;
transferring target scenario descriptions and validation scenario descriptions to target scenario scripts and validation scenario scripts, respectively, to create first raw simulation data pertaining to target scenario descriptions and second raw simulation data pertaining to validation scenario descriptions;
training, by an adjuster network, a deep neural network model to minimize differences between the first raw simulation data and the second raw simulation data;
refining the first and second raw simulation data of rare driving scenarios to generate rare driving scenario training data; and
outputting the rare driving scenario training data to a display screen of a computing device to enable a user to train a scenario detector for an autonomic driving assistant system (ADAS).

9. The computer program product of claim 8, wherein the target scenario scripts and the validation scenario scripts are generated based on position and behavior definitions, and parameter and constraints definitions.

10. The computer program product of claim 8, wherein the adjuster network includes a long short-term memory (LSTM) encoder and a decoder.

11. The computer program product of claim 10, wherein the LSTM encoder transforms the first and second raw simulation data into high dimensional features.

12. The computer program product of claim 11, wherein the decoder constructs the rare driving scenario training data from the high dimensional features.

13. The computer program product of claim 12, wherein a model trainer takes the first and second raw simulation data as input and outputs the rare driving scenario training data.

14. The computer program product of claim 13, wherein the model trainer compares the rare driving scenario training data with the real data of the validation scenario and determines a difference therebetween to be minimized.

15. A computer processing system for simulating vehicle data and improving driving scenario detection, comprising:
a memory device for storing program code; and
a processor device, operatively coupled to the memory device, for running the program code to:
retrieve, from vehicle sensors, key parameters from real data of validation scenarios to generate corresponding scenario configurations and descriptions;
transfer target scenario descriptions and validation scenario descriptions to target scenario scripts and validation scenario scripts, respectively, to create first raw simulation data pertaining to target scenario descriptions and second raw simulation data pertaining to validation scenario descriptions;
train, by an adjuster network, a deep neural network model to minimize differences between the first raw simulation data and the second raw simulation data;
refine the first and second raw simulation data of rare driving scenarios to generate rare driving scenario training data; and
output the rare driving scenario training data to a display screen of a computing device to enable a user to train a scenario detector for an autonomic driving assistant system (ADAS).

16. The computer processing system of claim 15, wherein the target scenario scripts and the validation scenario scripts are generated based on position and behavior definitions, and parameter and constraints definitions.

17. The computer processing system of claim 15, wherein the adjuster network includes a long short-term memory (LSTM) encoder and a decoder.

18. The computer processing system of claim 17, wherein the LSTM encoder transforms the first and second raw simulation data into high dimensional features.

19. The computer processing system of claim 18, wherein the decoder constructs the rare driving scenario training data from the high dimensional features.

20. The computer processing system of claim 19,
wherein a model trainer takes the first and second raw simulation data as input and outputs the rare driving scenario training data; and
wherein the model trainer compares the rare driving scenario training data with the real data of the validation scenario and determines a difference therebetween to be minimized.
